(19) United States
(12) Patent Application Publication
(10) Pub. No.: US 2021/0012973 A1
(43) Pub. Date: Jan. 14, 2021

(54) OPTOELECTRONIC MODULE

(71) Applicant: Tetsuya HONDA, Shizuoka (JP)

(72) Inventor: Tetsuya HONDA, Shizuoka (JP)

(73) Assignee: Ricoh Company, Ltd., Tokyo (JP)

(21) Appl. No.: 16/919,380

(22) Filed: Jul. 2, 2020

(30) Foreign Application Priority Data
Jul. 8, 2019 (JP) 2019-127161

(51) Int. Cl. H01G 9/20

(52) U.S. Cl. CPC H01G 9/2059; H01G 9/2081

(57) ABSTRACT

An optoelectronic module includes a substrate, at least one optoelectronic element provided on a predetermined surface of the substrate, and a spacer disposed farther outward than the optoelectronic element and on the predetermined surface of the substrate, the spacer having a height greater than a thickness of the optoelectronic element. The spacer is disposed to allow for a gap between a member and the optoelectronic element, the spacer being provided in contact with the member, and the optoelectronic element being interposed between the substrate and the member.

### CROSS-REFERENCE TO RELATED APPLICATION

The present application claims priority under 35 U.S.C. § 119 to Japanese Patent Application No. 2019-127161, filed Jul. 8, 2019, the contents of which are incorporated herein by reference in their entirety.

### BACKGROUND OF THE INVENTION

### 1. Field of the Invention

The present disclosure relates to an optoelectronic module.

### 2. Description of the Related Art

In recent years, optoelectronic elements have become increasingly important, from the viewpoint of replacement energy for fossil fuels and measures against global warming. Especially in recent years, optoelectronic elements for indoor use have attracted much attention because the optoelectronic elements can be expected to be widely applied as self-contained power sources, each of which does not require a battery replacement, power wirings, and the like. Such an optoelectronic element allows for efficiently generated power, even in a low-light environment.

Examples of the optoelectronic element include an amorphous silicon solar cell, an organic thin film solar cell, a perovskite solar cell, a dye-sensitized solar cell, and the like. For example, when a dye-sensitized solar cell is mounted on indoor furniture or the interior, a technique of reusing a portion of energy consumed by room lighting is disclosed. Further, when the dye-sensitized solar cell is mounted on a room wall, a protective sheet is attached to the dye-sensitized solar cell. Thereby, preventing of damage to the solar cell is disclosed (e.g., WO17/099114 hereinafter referred to as Patent document 1).

### SUMMARY

An optoelectronic module includes a substrate, at least one optoelectronic element provided on a predetermined surface of the substrate, and a spacer disposed farther outward than the optoelectronic element and on the predetermined surface of the substrate, the spacer having a height greater than a thickness of the optoelectronic element. The spacer is disposed to allow for a gap between a member and the optoelectronic element, the spacer being provided in contact with the member, and the optoelectronic element being interposed between the substrate and the member.

### BRIEF DESCRIPTION OF THE DRAWINGS

FIG. 1 is a plan view of an example of an optoelectronic module according to a first embodiment;

FIG. 2 is a cross-sectional view of an example of the optoelectronic module according to the first embodiment;

FIG. 3 is a plan view of an example of a power generator of an optoelectronic element according to the first embodiment;

FIG. 4 is a plan view of an optoelectronic module according to a comparative example;

FIG. 5 is a cross-sectional view of the optoelectronic module according to the comparative example;

FIG. 6 is a plan view of an example of an optoelectronic module according to modification 1 of the first embodiment;

FIG. 7 is a cross-sectional view of an example of the optoelectronic module according to modification 1 of the first embodiment;

FIG. 8 is a plan view of an example of an optoelectronic module according to a second embodiment;

FIG. 9 is a cross-sectional view of an example of the optoelectronic module according to the second embodiment;

FIG. 10 is a cross-sectional view of an example of the optoelectronic module according to modification 1 of the second embodiment;

FIG. 11 is a cross-sectional view of an example of an optoelectronic module according to modification 2 of the second embodiment; and

FIG. 12 is a table illustrating the result for examples and comparative example.

### DETAILED DESCRIPTION OF THE EMBODIMENTS

One or more embodiments will be hereinafter described with reference to the drawings. In each figure, the same reference numerals are used to denote the same components; accordingly, duplicate explanation for the components may be omitted.

### First Embodiment

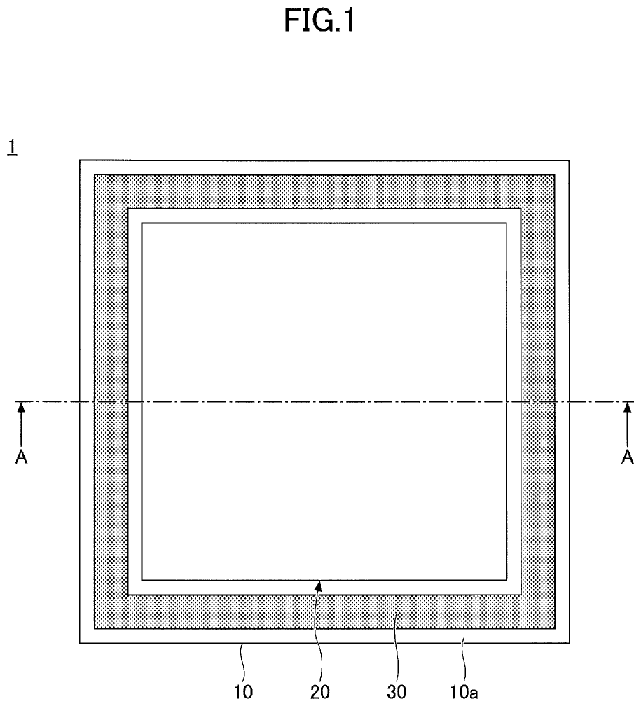

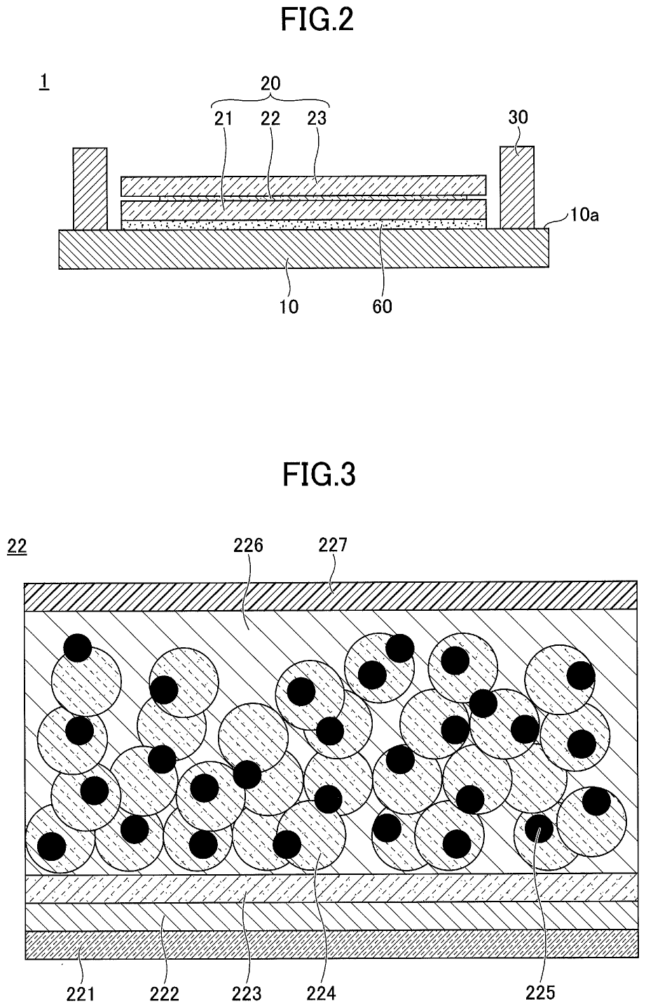

FIG. 1 is a plan view of an example of an optoelectronic module according to a first embodiment. FIG. 2 is a cross-sectional view of an example of the optoelectronic module according to the first embodiment, and illustrates a cross section taken along the A-A line in FIG. 1.

Referring to FIGS. 1 and 2, the optoelectronic module 1 includes a substrate 10, an optoelectronic element 20, and a spacer 30.

The substrate 10 is a substrate on which the optoelectronic element 20 and the like are provided. The substrate 10 has an interconnect pattern for electrically connecting one or more lands including components, as well as electrically connecting target parts of components. As the substrate 10, for example, a resin substrate (e.g., a glass epoxy substrate or the like), a glass substrate, a silicon substrate, a ceramic substrate, or the like is used as appropriate.

The present embodiment will be described below using the substrate 10 having the rectangular planar shape, as an example. However, the planar shape of the substrate 10 is not limited to the rectangular shape. Note that a plan view means that an object is viewed from the direction normal to the upper surface 10a of the substrate 10. The planar shape refers to an object shape viewed from the direction normal to the upper surface 10a of the substrate 10.

The optoelectronic element 20 includes a substrate 21, a power generator 22, and a substrate 23. The power generator 22 is interposed between the substrate 21 and the substrate 23, in the vertical direction. The perimeter of the power generator 22 may be sealed with a resin or the like.

The optoelectronic element 20 of which a light receiving surface is oriented upward (the side not facing the upper surface 10a of the substrate 10) is provided on the upper surface 10a of the substrate 10. The optoelectronic element 20 is fixed to the upper surface 10a of the substrate 10 via an adhesive layer 60, for example. Examples of the adhesive layer 60 include a resin-based adhesive, a double-sided tape, and the like.

The substrate 23 is transparent, and sunlight or the like enters the light receiving surface of the power generator 22, via the substrate 23. The substrates 21 and 23 are each formed of, for example, glass. Note that a plurality of optoelectronic elements 20 may be provided on one substrate 10. In this case, the plurality of optoelectronic elements 20 may be electrically connected in parallel, or be electrically connected in series.

The optoelectronic element 20 is an element that converts light energy into electrical energy. Examples of the optoelectronic element 20 include a solar cell, a photodiode, and the like. Examples of the solar cell include an amorphous silicon solar cell, an organic thin film solar cell, a perovskite solar cell, a dye-sensitized solar cell, and the like.

Among the above examples, the dye-sensitized solar cell is advantageous for cost reduction, because the dye-sensitized solar cell can be manufactured by a conventional printing method. Particularly, a solid dye-sensitized solar cell that constitutes the dye-sensitized solar cell and in which a hole transporting layer is formed of a solid material, is preferable from the viewpoint of maintaining increased resistance to load.

FIG. 3 is a cross-sectional view of an example of the power generator of the optoelectronic element. When the optoelectronic element 20 is a dye-sensitized solar cell, the power generator 22 has the cross-sectional structure illustrated in FIG. 3, for example.

In the example of the structure of the power generator 22 illustrated in FIG. 3, a first electrode 222 is formed on a substrate 221, a hole blocking layer 223 is formed on the first electrode 222, and an electron transporting layer 224 is formed on the hole blocking layer 223. Photosensitized compounds 225 are adsorbed in an electron transporting material in the electron transporting layer 224. A hole transporting layer 226 is interposed between the first electrode 222 and the second electrode 227 that faces the first electrode 222. The first electrode 222 is connected to a positive terminal through, for example, a lead wire or the like. The second electrode 227 is connected to a negative terminal through, for example, a lead wire or the like. The power generator 22 will be described below in detail.

[Substrate]

The substrate 221 is not particularly restricted, and can be implemented by any known substrate. The substrate 221 is preferably formed of a transparent material. Examples of the material include glass, a transparent plastic plate, a transparent plastic film, an inorganic transparent crystal, and the like.

[First Electrode]

The first electrode 222 is not particularly restricted as long as the first electrode 222 is formed of a conductive material that is transparent to visible light. The first electrode 222 can be appropriately selected for any purpose. As the first electrode 222, a general optoelectronic element, or any known electrode used in a liquid crystal panel or the like can be used.

Examples of the material of the first electrode 222 include indium-tin oxide (ITO), fluorine-doped tin oxide (FTO); antimony-doped tin oxide (ATO); indium-zinc oxide; niobium-titanium oxide; graphene; and the like. One material from among the above examples may be used alone, or a combination of two or more materials from among the above examples may be used.

The thickness of the first electrode 222 is preferably between 5 nm and 100 μm, and more preferably between 50 nm and 10 μm.

In order to maintain certain hardness, the first electrode 222 is preferably provided on the substrate 221 formed of material that is transparent to visible light. Note that any known component in which the first electrode 222 and the substrate 221 are integrated can be used. Examples of the above component include FTO coated glass; ITO coated glass; zinc oxide-doped aluminum coated glass; an FTO coated transparent plastic film; an ITO coated transparent plastic film; and the like.

[Hole Blocking Layer]

The hole blocking layer 223 is provided to avoid reduction in power due to recombination (back electron transfer) of a hole in an electrolyte with an electron on the electrode surface, when the electrolyte contacts the electrode. Particularly, with respect to the solid dye-sensitized solar cell, the hole blocking layer 223 has the above effect noticeably. This is because the solid dye-sensitized solar cell using an organic hole transporting material or the like has an increased rate of recombination (back electron transfer) of the hole in the hole transporting material with the electron on the electrode surface, in comparison to a wet dye-sensitized solar cell using an electrolyte.

The hole blocking layer 223 preferably includes a metal oxide containing the titanium atom and the niobium atom. As necessary, another metal atom may be included. The hole blocking layer 223 is preferably formed of metal oxide containing the titanium atom and the niobium atom. The hole blocking layer 223 is preferably transparent to visible light, and the hole blocking layer 223 is preferably dense in order to serve as a hole blocking layer.

The mean thickness of the hole blocking layer 223 is preferably 1,000 nm or less, and more preferably between 0.5 nm and 500 nm. When the mean thickness of the hole blocking layer 223 is in the range of from 0.5 nm to 500 nm, back electron transfer can be avoided without preventing the transfer of the electron to a transparent conductive film (first electrode 222). Thereby, photovoltaic conversion efficiency can be improved. Also, when the mean thickness of the hole blocking layer 223 is less than 0.5 nm, a film density decreases and thus the back electron transfer cannot be sufficiently avoided. When the mean thickness of the hole blocking layer 223 exceeds 500 nm, internal stress increases and thus cracks are more likely to occur.

[Electron Transporting Layer]

The electron transporting layer 224, which is an example of a porous layer, is formed on the hole blocking layer 223. Preferably, the electron transporting layer 224 includes an electron transporting material such as a semiconducting-micro particle or metal oxide. The electron transporting material preferably adsorbs the photosensitized compounds 225 described below.

The electron transporting material is not particularly restricted, and can be selected for any purpose. The electron transporting material is preferably a semiconducting material such as a rod-shaped material or a tubular material. In the following description, the semiconducting micro-particle may be described by way of example. However, the electron transporting material is not limited to the semiconducting micro-particle.

The electron transporting layer 224 may be a single layer or a multilayer. In the case of the multilayer, dispersion liquid of the semiconducting micro-particles each having a different particle size can be painted on the multilayer. Alternatively, different semiconductors can be painted on the multilayer, or, paint layers having different compositions of a resin and additive can be painted on the multilayer. When the thickness of the electron transporting layer formed with one paint is not sufficient, the multilayer paint is effective.

The semiconductor is not particularly restricted, and any known semiconductor can be used as the semiconductor. Specifically, the semiconductor can include a single semiconductor such as silicon or germanium; a compound semiconductor such as metal chalcogenide; a compound having a perovskite structure; or the like.

The particle size of the semiconducting micro-particle is not particularly restricted, and can be appropriately selected for any purpose. The mean particle size of the primary particle is preferably between 1 nm and 100 nm, and more preferably between 5 nm and 50 nm. When the semiconducting micro-particles having an increased mean particle size are mixed or laminated, incident light is diffused. Such an effect can improve the electron transfer efficiency. In this case, the mean particle size of the semiconducting micro-particle is preferably between 50 nm and 500 nm.

In general, an amount of bearing photosensitized compounds per projected area unit increases as the thickness of the electron transporting layer 224 increases, and a capture rate of light increases accordingly. However, because a diffusion distance of an injected electron increases, loss due to charge recombination increases. From the viewpoint described above, the thickness of the electron transporting layer 224 is preferably between 100 nm and 100 μm, more preferably between 100 nm and 50 μm, and further more preferably between 100 nm and 10 μm.

[Photosensitive Compound] In order to further improve the conversion efficiency, the electron transporting layer 224 preferably includes an electron transporting material that absorbs the photosensitized compound 225 (dye). A specific example of the photosensitized compound 225 is described in detail, for example, in Japanese Patent No. 6249093.

As a method of adsorbing the photosensitized compounds 225 in the electron transporting layer 224 (electron transporting material), a method of immersing an electron collecting electrode (an electrode in which the substrate 221, the first electrode 222, and the hole blocking layer 223 are formed) including the electron transporting layer 224, in a solution or dispersion liquid of the photosensitized compounds 225 is used. Another method of painting a solution or dispersion liquid on the electron transporting layer 224, for adsorption can be used.

In the case of the method of immersing an electron collecting electrode, a soaking method, a dip method, a roller method, an air knife method, or the like can be used. In the case of the method of painting a solution or dispersion liquid, a wire bar method, a slide hopper method, an extrusion method, a curtain method, a spin method, a spray method, or the like can be used.

Adsorption may be achieved in a supercritical fluid using carbon dioxide or the like.

A condensation agent may be concomitantly used in adsorbing the photosensitized compounds 225. The condensation agent may include an agent having a catalytic action to be assumed to physically or chemically combine the photosensitized compound 225 with the electron transporting material on the inorganic surface; or an agent that acts stoichiometrically to advantageously cause chemical equilibrium.

[Hole Transporting Layer]

The hole transporting layer 226 includes an electrolyte solution in which a redox pair is dissolved in an organic solvent; a gel electrolyte in which liquid in which a redox pair is dissolved in an organic solvent is impregnated in a polymer matrix; a molten salt containing a redox pair; a solid electrolyte; an inorganic hole transporting material; an organic hole transporting material; or the like. Among the examples described above, the organic hole transporting material is preferred. Note that in the following description, the organic hole transporting material will be described as an example. However, the hole transporting layer 226 is not limited to being formed of the organic hole transporting material.

The hole transporting layer 226 may be a single-layer structure formed of a single material, or a laminated structure formed of multiple compounds. In the case of the laminated structure, a polymeric material is preferably used in the hole transporting layer 226 proximal to the second electrode 227. When a polymeric material with excellent deposition is used, the surface of the porous electron transporting layer 224 can be smoothed. Thereby, photovoltaic conversion characteristics can be improved.

Because the polymer material is less likely to permeate the porous electron transporting layer 224, the surface of the porous electron transporting layer 224 is excellent in coating. Thus, the polymer material is effective in preventing short-circuiting when the electrode is provided. Accordingly, a higher performance can be achieved.

The organic hole transporting material used in the single-layer structure formed of a single material is not particularly restricted, and any known organic hole transporting compound is used.

The thickness of the hole transporting layer 226 is not particularly restricted, and can be selected for any purpose. The hole transporting layer 226 preferably has a structure of being embedded into pores of the porous electron transporting layer 224. The thickness of the hole transporting layer 226 on the electron transporting layer 224 is more preferably 0.01 μm or more, and further preferably between 0.1 μm and 10 μm.

[Second Electrode]

The second electrode 227 can be formed on the hole transporting layer 226; or on metal oxide in the hole transporting layer 226. As the second electrode 227, an electrode that is the same as the first electrode 222 can be used. When the second electrode 227 has the configuration of strength and a seal performance being sufficiently maintained, a support is not necessarily required.

Examples of the material of the second electrode 227 include metal such as platinum, gold, silver, copper, and aluminum; a carbon-based compound such as graphite, fullerene, a carbon nanotube, or graphene; conductive metal oxide such as ITO, FTO, or ATO; a conductive polymer such as polythiophene or polyaniline; and the like.

The thickness of the second electrode 227 is not particularly restricted, and can be appropriately selected for any purpose. Taking into account target material and a hole transporting layer 226 type, the second electrode 227 can be appropriately formed on the hole transporting layer 226, by painting, lamination, vapor deposition, chemical vapor deposition (CDV), bonding, or the like.

Note that at least one of the first electrode 222 and the second electrode 227 is required to be substantially transparent in order for the power generator to perform photovoltaic conversion. In the example of FIG. 3, the first electrode 222 is transparent and thus sunlight or the like is incident from the first electrode 222 side.

In such a manner, in the optoelectronic module 1, the first electrode 222 is positioned toward the substrate 23, and the power generator 22 is disposed between the substrate 21 and the substrate 23. In this case, material that reflects light is preferably used in the second electrode 227. For example, such material includes metal; glass in which conductive oxide is deposited; plastic; a thin metallic film; or the like. Advantageously, an anti-reflection layer is provided on the side of light being incident.

The optoelectronic element 20 including the power generator 22 can have increased conversion efficiency, even in the case of low incident light, such as indoor light.

Referring back to FIGS. 1 and 2, a spacer 30 having a height greater than the thickness of the optoelectronic element 20 is disposed farther outward than the optoelectronic element 20 and on the upper surface 10a of the substrate 10. The spacer 30 is a frame-like member that is continuously disposed and that surrounds the outer periphery of the optoelectronic element 20. For example, with an adhesive or the like, the spacer 30 is fixed proximal to the outer periphery of the substrate 10 and on the upper surface 10a of the substrate 10. The inner surface of the spacer 30 is apart from the outer periphery of the optoelectronic element 20.

For example, a transparent member is disposed on the spacer 30. When the transparent member is disposed on the spacer 30 that contacts the transparent member, and the optoelectronic element 20 is interposed between the substrate 10 and the transparent member, the spacer 30 can be disposed to allow for a gap between the member and the optoelectronic element 20.

For example, when there is only one columnar spacer having a height greater than the thickness of the optoelectronic element 20, the condition for a gap is not met. When the transparent member is disposed on the spacer 30, the spacer 30 needs to be disposed to allow for the gap between the member and the optoelectronic element 20.

The spacer 30 is continuously disposed to surround the outer periphery of the optoelectronic element 20. In such a manner, when the transparent member is disposed on the spacer 30, the gap between the member and the optoelectronic element 20 can be secured.

The material of the spacer 30 is not particularly restricted, and can include a rigid material such as metal, glass, or plastic. Alternatively, the material of the spacer 30 may include an elastomeric material such as rubber. Note, however, that when the elastomeric material is used as the material of the spacer 30, in a case where load is applied to the spacer 30 through the transparent member, the spacer 30 preferably has a height in which the transparent member does not contact the optoelectronic element 20.

Taking into account deflection of a target member to be disposed on the spacer 30; and load assumed to be applied to the target member, the spacer 30 preferably has the height in which, when the assumed load is actually applied to the member, the member does not contact the optoelectronic element 20.

Specifically, the height of the spacer 30 is set to allow the gap between the target member to be disposed on the spacer 30, and the optoelectronic element 20 to be greater than a predetermined value, taking into account a maximum deflection amount of the member. The predetermined value for the gap is calculated based on the maximum deflection amount, the maximum deflection amount being assumed when equally distributed load is applied to a rectangular glass of which four sides are supported by respective support posts.

Specifically, the height of the spacer 30 is set taking into account the maximum deflection amount that is calculated by δC=αWa⁴/Et² (Formula 1). Where, δC represents the maximum deflection amount, W represents (equally distributed) load (MPa), a represents the length (mm) of the short side of the rectangular glass, and b represents the length (mm) of the long side of the rectangular glass. Further, α represents the deflection coefficient in accordance with a ratio of the short side to the long side, t represents the thickness (mm) of the rectangular glass, and E represents the Young's modulus (MPa) of the rectangular glass.

For example, when load of W=1 MPa is applied to the rectangular glass where, in Formula 1, a=88 mm; b=264 mm (α=0.139); the thickness t=5 mm; and the Young's modulus E=7.16×10⁴ MPa, the maximum deflection amount of δC≈4.7 mm is calculated from Formula 1 above.

In this case, the member and the optoelectronic element 20 are desirably separated by the above maximum deflection amount or more. For example, the member and the optoelectronic element 20 are separated by a distance of 4.7 mm or more. In consideration to manufacturing variation, it is desirable to consider an error of about 1% with respect to the thickness of the member.

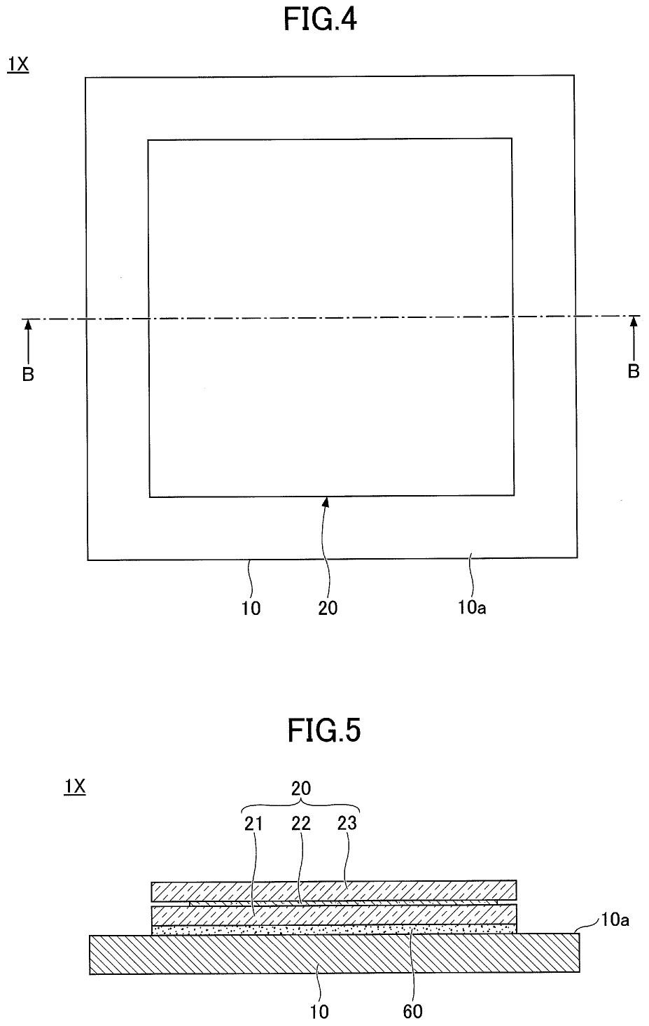

FIG. 4 is a plan view of an optoelectronic module according to the comparative example. FIG. 5 is a cross-sectional view of the optoelectronic module according to the comparative example, and illustrates a cross-section taken along the B-B line in FIG. 4.

Referring to FIGS. 4 and 5, the optoelectronic module 1X differs from the optoelectronic module 1 (see FIGS. 1 and 2) in that the optoelectronic module 1X does not have the spacer 30.

When the optoelectronic module 1X illustrated in FIGS. 4 and 5 is not provided with the spacer 30, in a case where, for example, the member is placed on the optoelectronic module 1X, surface load is directly applied to the optoelectronic element 20. For this reason, the power of the optoelectronic element 20 is greatly decreased due to damage, etc. of the power generator 22 within the optoelectronic element 20; the substrate 23 in the surface of the optoelectronic element 20; or the like.

In contrast, for the optoelectronic module 1 illustrated in FIGS. 1 and 2, the height of the spacer 30 is greater than the thickness of the optoelectronic element 20. In this case, for example, even when the member is placed on the optoelectronic module 1, the gap between the member and the optoelectronic element 20 can be secured.

Thus, surface load is not applied to the optoelectronic element 20, and the optoelectronic element 20 is not deteriorated. Accordingly, the optoelectronic element 20 can maintain the increased power.

As described above, the optoelectronic module 1 has the spacer 30 having the height greater than the thickness of the optoelectronic element 20. When the transparent member is disposed on the spacer 30, the spacer 30 is disposed to allow for the gap between the member and the optoelectronic element 20.

In such a manner, even when external load is applied to the transparent member and thus the member is deflected, the external load is not applied directly to the optoelectronic element 20. As a result, deterioration of the optoelectronic element 20 due to the external load can be prevented. Accordingly, the optoelectronic element 20 can maintain the increased power.

Particularly, when the electrolyte of the optoelectronic element 20 is liquid, the spacer 30 allows for the space between the member and the optoelectronic element 20. Further, damage to the optoelectronic element 20 due to the external load can be prevented. Accordingly, the spacer 30 is useful from the viewpoint of preventing leakage of liquid.

Note that it is not preferable that the space between the transparent member and the optoelectronic element 20 be filled with a resin or the like. This is because, when the member is deflected due to external load on the transparent member, the external load is applied to the optoelectronic element 20 through a resin or the like, which may result in deterioration of the optoelectronic element 20. Setting of the gap between the transparent member and the optoelectronic element 20 is extremely important.

Note that the spacer 30 is preferably white. Even in the case where the spacer 30 has a color other than white, resistance to external load is sufficiently obtained. The white spacer 30 reflects light to be concentrated in the optoelectronic element 20. Thereby, the power of the optoelectronic element 20 can be further increased.

The substrate 10 and the spacer 30 may be integrally formed.

<Modification 1 of the First Embodiment>

Modification 1 of the first embodiment provides an example of an optoelectronic module having a spacer that has the shape different from the shape described in the first embodiment. Note that in the modification 1 of the first embodiment, the explanation for the same configuration as described in the above embodiment may be omitted.

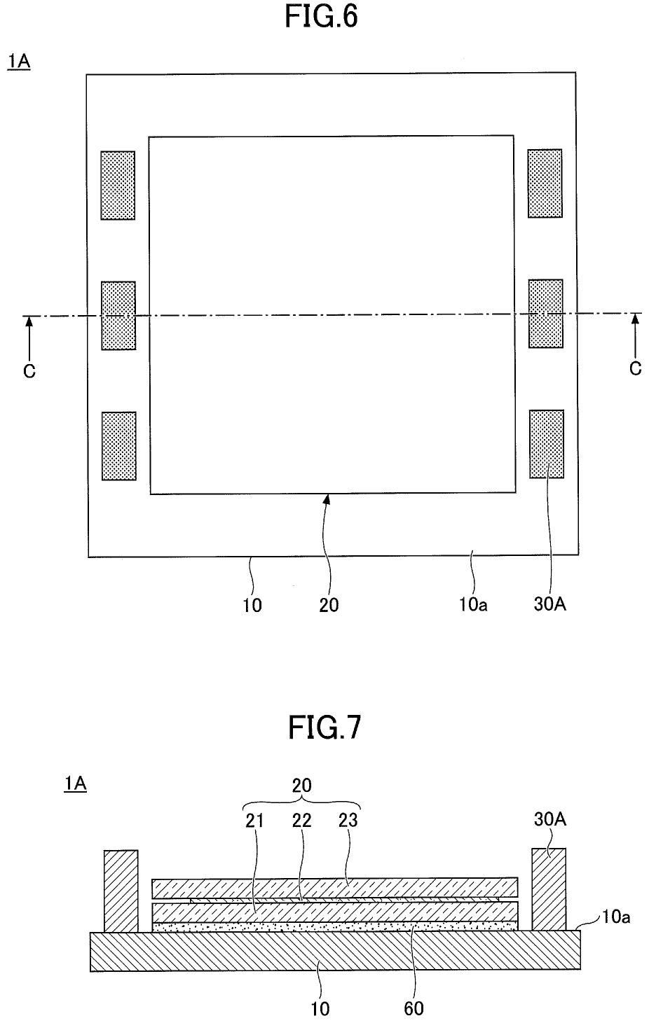

FIG. 6 is a plan view of an example of the optoelectronic module according to the modification 1 of the first embodiment. FIG. 7 is a cross-sectional view of an example of the optoelectronic module according to the modification 1 of the first embodiment, and illustrates a cross section taken along the C-C line in FIG. 6.

Referring to FIGS. 6 and 7, the optoelectronic module 1A differs from the optoelectronic module 1 (see FIGS. 1 and 2) in that the spacer 30 is replaced with spacers 30A. The spacer 30 has the continuous shape, while the spacers 30A are discontinuously arranged.

In the example illustrated in FIGS. 6 and 7, three spacers 30A are disposed outside each of two opposite sides of the optoelectronic element 20, the optoelectronic element 20 being interposed in a plan view. Each spacer 30A has a height greater than the thickness of the optoelectronic element 20, and is disposed farther outward than the optoelectronic element 20 and on the upper surface 10a of the substrate 10. The spacers 30A are members that are discontinuously arranged to surround the outer periphery of the optoelectronic element 20. For example, each spacer 30A is fixed to the upper surface 10a of the substrate 10 proximal to the outer periphery of the substrate 10, with an adhesive. The inner surface of each spacer 30A is apart from the outer periphery of the optoelectronic element 20.

As is the case with the spacer 30, when a transparent member is disposed on the spacers 30A that contact the transparent member, and the optoelectronic element 20 is interposed between the substrate 10 and the transparent member, the spacers 30A can be disposed to allow for a gap between the member and the optoelectronic element 20.

Note, however, that the arrangement of the spacers in FIGS. 6 and 7 is described as an example. For example, the plurality of spacers 30A may be discontinuously arranged outside of four sides of the optoelectronic element 20, at predetermined intervals. Alternatively, respective L-shaped spacers 30A may be discontinuously arranged proximal to four corners of the optoelectronic element 20. Other arrangements of the spacers may be achieved.

The material of the spacer 30A is not particularly restricted, and can be appropriately selected from among the examples of the material having been described in the spacer 30. As is the case with the spacer 30, taking into account deflection of a target member to be disposed on the spacers 30A; and load assumed to be applied to the target member, each spacer 30A preferably has the height in which, when the assumed load is actually applied to the member, the member does not contact the optoelectronic element 20.

As described above, the spacer may have the continuous shape, or the spacers may be discontinuously arranged. The spacer having the continuous shape is effective from the viewpoint of strength.

### Second Embodiment

The second embodiment will be described using an example of an optoelectronic module in which a substrate is disposed on a spacer. Note that according to the second embodiment, explanation for the components that are the same as the components described in the above embodiment may be omitted.

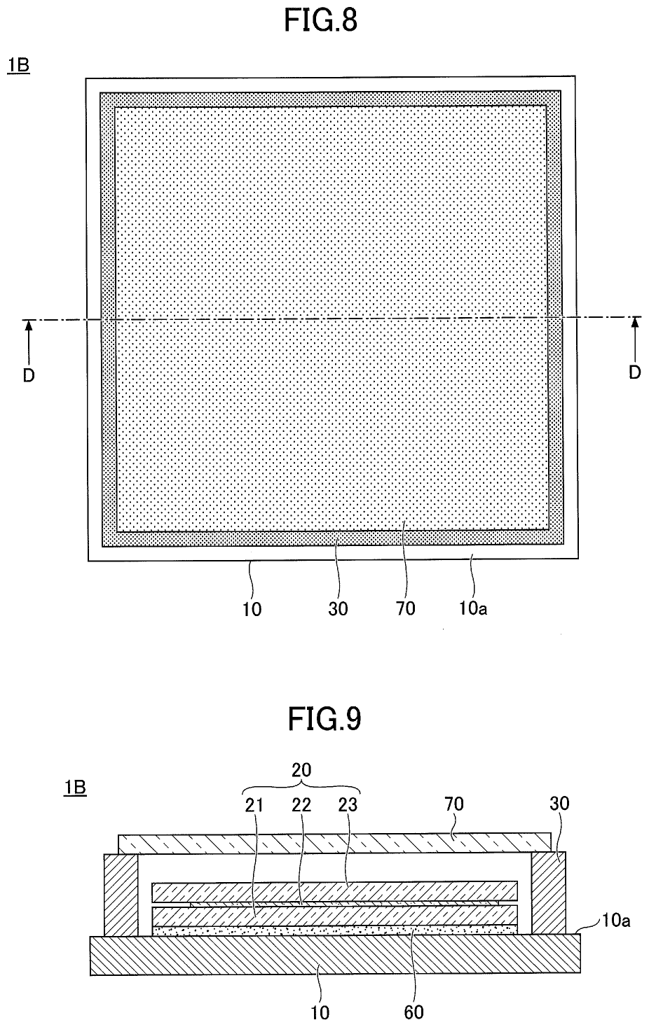

FIG. 8 is a plan view of an example of the optoelectronic module according to the second embodiment. FIG. 9 is a cross-sectional view of an example of the optoelectronic module according to the second embodiment, and illustrates a cross section taken along the D-D line in FIG. 8.

Referring to FIGS. 8 and 9, the optoelectronic module 1B differs from the optoelectronic module 1 (see FIGS. 1 and 2) in that the transparent substrate 70 is disposed on the spacer 30. Note that as the transparent substrate 70, a plurality of transparent substrates that are laminated may be used in order to increase strength. In this case, the material of each transparent substrate may be the same, or be different.

The transparent substrate 70 is disposed on the spacer 30 to contact the spacer 30. A gap between the transparent substrate 70 and the optoelectronic element 20 is secured.

Taking into account deflection of the transparent substrate 70 disposed on the spacer 30; and load assumed to be applied to the transparent substrate 70, the spacer 30 preferably has a height in which, when the assumed load is actually applied to the transparent substrate 70, the transparent substrate 70 does not contact the optoelectronic element 20.

The transparent substrate 70 preferably has a haze ratio between 0.1% and 16.0%. When the haze ratio of the transparent substrate 70 is greater than 16.0%, light incident on the transparent substrate 70 is scattered increasingly within the transparent substrate 70, and light is not sufficiently delivered to the optoelectronic element 20. Thereby, the power of the optoelectronic element 20 decreases.

In contrast, when the transparent substrate 70 has a haze ratio of less than 0.1%, light is directly transmitted without being scattered within the transparent substrate 70. In this case, scattering of light does not allow light to be efficiently focused onto the optoelectronic element 20. For example, the haze ratio of transparent substrate 70 is preferably between 0.1% and 16.0%, which allows light to be suitably scattered within the transparent substrate 70 to thereby efficiently focus the light onto the optoelectronic element 20.

Note that the haze ratio of the transparent substrate 70 is a ratio of a diffusion transmittance to a total light transmittance set when light is incident on the transparent substrate 70. The haze ratio is expressed with 0 through 100%. The haze ratio of the transparent substrate 70 can be measured using, for example, a haze meter HZ-1 (manufactured by Suga Test Instruments Co., Ltd.). Where, for a standard illuminant, illuminant C defined by the International commission on Illumination (CIE) is used with a light source.

The material of the transparent substrate 70 is particularly restricted when the material has a haze ratio in the range described above. From the viewpoint of strength and transparency, the material of the transparent substrate 70 preferably includes one or more materials from among glass, an acrylic resin, a polycarbonate resin, and a vinylidene chloride resin.

As described above, the optoelectronic module 1B includes the spacer 30 having the height greater than the thickness of the optoelectronic element 20. The spacer 30 is disposed to allow for the gap between the transparent substrate 70 disposed on the spacer 30 and the optoelectronic element 20.

In such a manner, even when the transparent substrate 70 is deflected due to external load on the transparent substrate 70, the external load is not directly applied to the optoelectronic element 20. As a result, deterioration of the optoelectronic element 20 due to the external load can be prevented. Accordingly, the optoelectronic element 20 can maintain the increased power.

With the transparent substrate 70 being disposed on the spacer 30, resistance to local load can be improved.

Note that, for example, applying of an ultraviolet protection film to the transparent substrate 70, or the like may allow the transparent substrate 70 to have functions of cutting ultraviolet light. Thereby, deterioration of the optoelectronic element 20 due to ultraviolet light can be prevented.

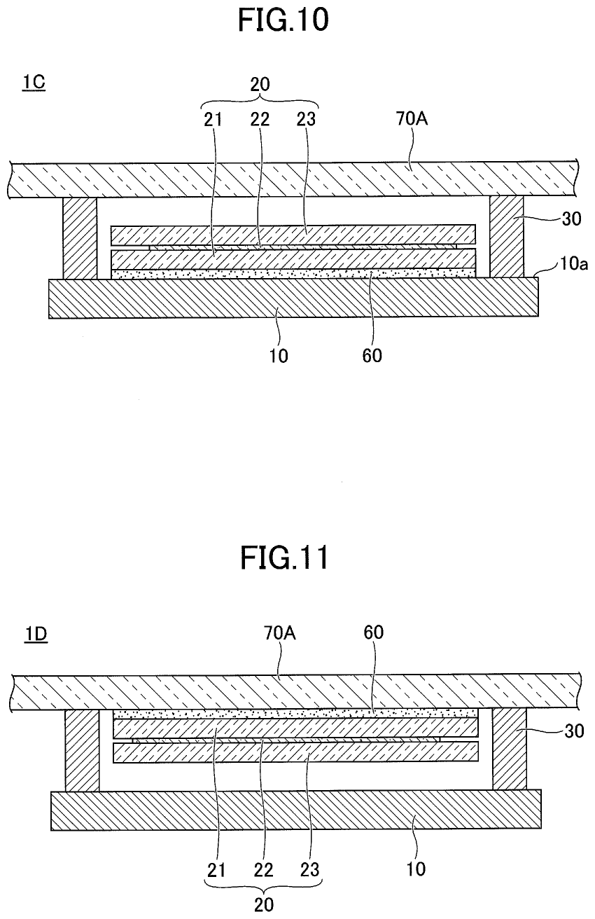

In an optoelectronic module 10 illustrated in FIG. 10, instead of the transparent substrate 70 of the optoelectronic module 1B, a member present at a location at which the optoelectronic module is provided may be used. For example, when the optoelectronic module 10 is placed on the back face of furniture (e.g., a desk, or the like) with a transparent top plate 70A (e.g., glass or an acrylic resin), the top plate 70A is a substitute for the transparent substrate 70 illustrated in FIG. 9, as illustrated in FIG. 10. In the optoelectronic module 1C, sunlight or the like enters a light receiving surface of a power generator 22, through the top plate 70A and the substrate 23.

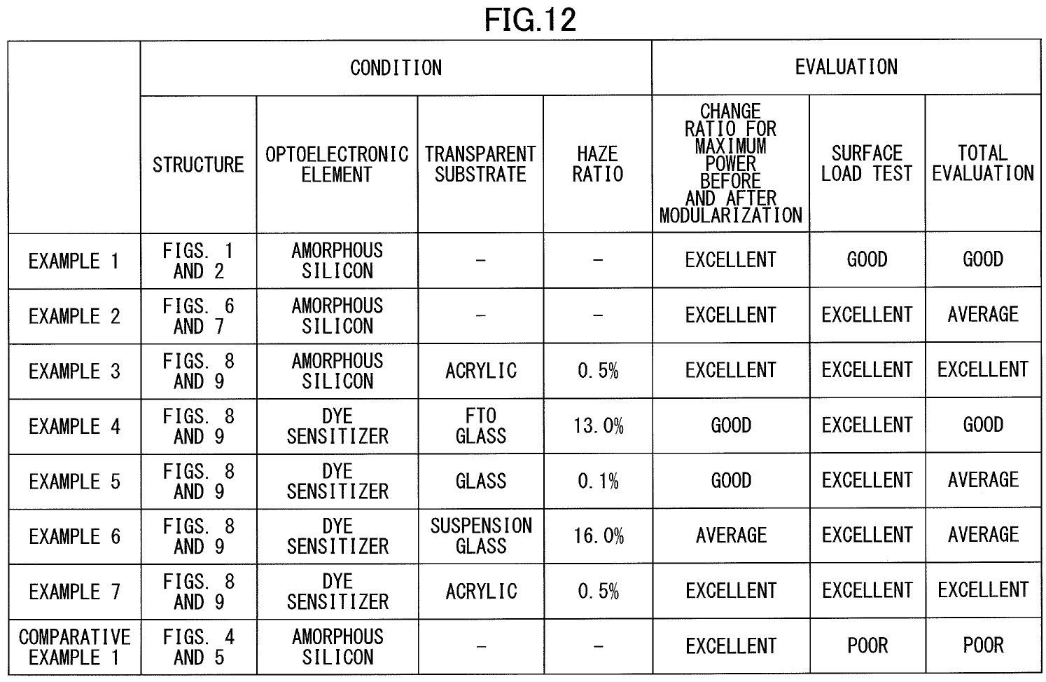

In an optoelectronic module 1D illustrated in FIG. 11, the optoelectronic element 20 may be directly formed on the back face of furniture with the transparent top plate 70A. In this case, the top plate 70A, an adhesive layer 60, and the substrate 21 are transparent. The optoelectronic element 20 in which the light receiving surface is oriented upward (the side facing the top plate 70A) is provided on the back face of the top plate 70A. In the optoelectronic module 1D, sunlight or the like enters the light receiving surface of the power generator 22, via the top plate 70A, the adhesive layer 60, and the substrate 21.

In the case in FIGS. 10 and 11, the optoelectronic modules 10 and 1D have the respective spacers 30 each of which has a height greater than the thickness of the optoelectronic element 20. In FIG. 10, the spacer 30 is disposed to allow for the gap between the top plate 70A disposed in contact with the spacer 30 and the optoelectronic element 20. In FIG. 11, the spacer 30 is disposed to allow for the gap between the optoelectronic element 20 and the substrate 10.

In such a manner, in the optoelectronic module 1C, even when the top plate 70A is deflected due to external load that is applied to the top plate 70A, the external load is not directly applied to the optoelectronic element 20. As a result, deterioration of the optoelectronic element 20 due to the external load can be prevented. Accordingly, the optoelectronic element 20 can maintain the increased power.

With the top plate 70A being disposed in contact with the spacer 30, resistance to local load can be improved.

In the optoelectronic module 1D, when the top plate 70A is deflected due to external load on the top plate 70A, the optoelectronic element 20 is deflected accordingly, as is the case with the top plate 70A. In this case, the optoelectronic element 20 does not contact the substrate 10. As a result, deterioration of the optoelectronic element 20 due to the external load can be prevented. Accordingly, the optoelectronic element 20 can maintain the increased power.

With the substrate 10 being provided, resistance to local load can be improved.

The optoelectronic module and the like will be described below in more detail with reference to examples and comparative example. However, the optoelectronic module is not limited to these examples.

### Example 1

<Fabrication of Optoelectronic Module>

An optoelectronic module A having the structure that is the same as the structure illustrated in FIGS. 1 and 2 was fabricated. Where, an amorphous silicon solar cell as the optoelectronic element 20 was disposed on the substrate 10, and the spacer 30 was further disposed.

<Evaluation of Optoelectronic Module>

(1) Initial Maximum Output Power

For the fabricated optoelectronic module A, a solar cell evaluation system (As-510-PV03, manufactured by NY Corporation) was used to evaluate current-voltage (I-V) characteristics, under a condition of illuminance of 200 lx adjusted using a white light-emitting diode (LED). In the evaluation, a change ratio for the maximum output power before and after modularization was calculated. Where, the change ratio for the maximum output power before and after modularization, refers to a ratio of the maximum output power Pmax (μW/cm²) after modularization, to the maximum output power Pmax (μW/cm²) before modularization.

(Evaluation Criteria)

Excellent (Pass): 98% or more
Good (Pass): 95% to 98% exclusive
Average (Psss): 90% to 95% exclusive
Poor (Fail): less than 90%

(2) Surface Load Test

The optoelectronic module A of which the surface was oriented downward was set on a flat test table. Uniform load was gradually applied to the surface of the optoelectronic module A, up to 2400 Pa, and then the maximum load was maintained for 1 hour.

Then, the optoelectronic module A was turned over, and the procedure was performed as in the case with the front surface of the optoelectronic module A. Such a procedure for the front surface and back surface of the optoelectronic module A was repeatedly performed three times in total.

After the test, I-V characteristics were evaluated to calculate a ratio of the maximum output power after the test, to the maximum output power before the test.

(Evaluation Criteria)

Excellent (Pass): 95% or more
Good (Pass): 90% to 95% exclusive
Average (Pass): 80% to 90% exclusive
Poor (Fail): less than 80%

### Example 2

An optoelectronic module B having the structure that was the same as the structure illustrated in FIGS. 6 and 7 was fabricated as in the case with Example 1, except that the spacers 30A were used instead of the spacer 30. For the optoelectronic module B, evaluation was performed as was the case with Example 1.

### Example 3

An optoelectronic module C having the structure that was the same as the structure illustrated in FIGS. 8 and 9 was fabricated as in the case with Example 1, except that an acrylic resin plate having a haze ratio of 0.50% was placed on the spacer 30. Where, the acrylic resin plate was used as the transparent substrate 70. For the optoelectronic module C, evaluation was performed as in the case with Example 1. Note that the haze ratio of the transparent substrate 70 was measured using, for example, the haze meter HZ-1 (manufactured by Suga Test Instruments Co., Ltd.). For a standard illuminant, illuminant C defined by the International commission on Illumination (CIE) was used with a light source (measurement for the haze ratio described above also applies to the following examples).

### Example 4

An optoelectronic module D having the structure that was the same as the structure illustrated in FIGS. 8 and 9 was fabricated as in the case with Example 1, except that a dye-sensitized solar cell was used as the optoelectronic element 20; and an FTO glass plate having a haze ratio of 13.0% was placed on the spacer 30. Where, the FTO glass plate was used as the transparent substrate 70. For the optoelectronic module D, evaluation was performed as was the case with Example 1.

### Example 5

An optoelectronic module E having the structure that was the same as the structure illustrated in FIGS. 8 and 9 was fabricated as in the case with Example 1, except that a dye-sensitized solar cell was used as the optoelectronic element 20; and a glass having a haze ratio of 0.1% was placed on the spacer 30. Where, the glass was used as the transparent substrate 70. For the optoelectronic module E, evaluation was performed as in the case with Example 1.

### Example 6

An optoelectronic module F having the structure that was the same as the structure illustrated in FIGS. 8 and 9 was fabricated as in the case with Example 1, except that a dye-sensitized solar cell was used as the optoelectronic element 20; and a suspension glass plate having a haze ratio of 16.0% was placed on the spacer 30. Where, the suspension glass plate was used as the transparent substrate 70. For the optoelectronic module F, evaluation was performed as in the case with Example 1.

### Example 7

An optoelectronic module G having the structure that was the same as the structure illustrated in FIGS. 8 and 9 was fabricated as in the case with Example 1, except that a dye-sensitized solar cell was used as the optoelectronic element 20; and an acrylic plate having a haze ratio of 0.5% was placed on the spacer 30. Where, the acrylic plate was used as the transparent substrate 70. For the optoelectronic module G, evaluation was performed as in the case with Example 1.

### Comparative Example 1

An optoelectronic module H having the structure that was the same as the structure illustrated in FIGS. 4 and 5 was fabricated as in the case with Example 1, except that the spacer was not disposed on the substrate 10. For the optoelectronic module H, evaluation was performed as in the case with Example 1.

<Evaluated Result for Optoelectronic Modules>

FIG. 12 illustrates the evaluated result for the optoelectronic modules A to H. In FIG. 12, with respect to total evaluation, “excellent”, “good”, and “average” each indicate “pass”, and “poor” indicates “fail”.

In FIG. 12, for each of the optoelectronic modules A to H, the change ratio for the maximum output power before and after modularization indicated “pass”.

In the surface load test for the optoelectronic modules A to G for Examples 1 to 7 in each of which either of the spacer 30 or the spacers 30A was provided, the results indicated “pass”. In contrast, for the optoelectronic module H for the comparative example in which the spacer was not provided, the result indicated “fail”. From the results, it was confirmed that one or more spacers allowed increased stability with respect to the surface load to be maintained.

In the surface load test, particularly, the results for the optoelectronic modules C to G for Examples 3 to 7 in each of which the transparent substrate was provided, indicated “excellent”. It was confirmed that the transparent substrate allowed further increased stability with respect to the surface load to be maintained.

The preferred embodiments and the like have been described above in detail. However, various modifications or substitutions of the above embodiments and the like can be made without departing from the scope in the present disclosure.

What is claimed is:

1. An optoelectronic module comprising:
a substrate;
at least one optoelectronic element provided on a predetermined surface of the substrate; and
a spacer disposed farther outward than the optoelectronic element and on the predetermined surface of the substrate, the spacer having a height greater than a thickness of the optoelectronic element,
wherein the spacer is disposed to allow for a gap between a member and the optoelectronic element, the spacer being provided in contact with the member, and the optoelectronic element being interposed between the substrate and the member.

2. The optoelectronic module according to claim 1, wherein the spacer is continuously disposed to surround an outer periphery of the optoelectronic element.

3. The optoelectronic module according to claim 1, wherein the member being a transparent substrate is disposed in contact with the spacer to allow for the gap between the transparent substrate and the optoelectronic element.

4. The optoelectronic module according to claim 3, wherein the transparent substrate has a haze ratio between 0.1% and 16.0%.

5. The optoelectronic module according to claim 3, wherein the transparent substrate is formed of one or more from among glass, an acrylic resin, a polycarbonate resin, and a vinylidene chloride resin.

6. The optoelectronic module according to claim 1, wherein the at least one optoelectronic element is a plurality of optoelectronic elements, the plurality of optoelectronic elements being disposed on the substrate.

7. The optoelectronic module according to claim 6, wherein the plurality of optoelectronic elements are electrically connected in parallel.

8. The optoelectronic module according to claim 6, wherein the plurality of optoelectronic elements are electrically connected in series.

9. The optoelectronic module according to claim 1, wherein the spacer is white.

10. The optoelectronic module according to claim 1, wherein the optoelectronic element includes a power generator that includes a first electrode; a porous electron transporting layer; a hole transporting layer; and a second electrode, the electron transporting layer including an electron transporting material that absorbs dye.

11. The optoelectronic module according to claim 10, wherein a solid material is used in the hole transporting layer.
